(19) United States
(12) Patent Application Publication
(10) Pub. No.: US 2011/0200918 A1
(43) Pub. Date: Aug. 18, 2011

(54) PHOTOSENSITIVE COMPOSITION FOR VOLUME HOLOGRAM RECORDING AND PRODUCING METHOD THEREOF

(76) Inventors: Tomoya Mizuta, Hyogo (JP); Hiroto Miyake, Hyogo (JP)

(21) Appl. No.: 13/124,813

(22) PCT Filed: Oct. 28, 2009
(86) PCT No.: PCT/JP2009/005688

§ 371 Date: Apr. 18, 2011

(30) Foreign Application Priority Data
Nov. 8, 2008 (JP) 2008-287228
Nov. 8, 2008 (JP) 2008-287229

(51) Int. Cl. G03F 7/00

(52) U.S. Cl. 430/2

(57) ABSTRACT

A photosensitive composition (I) for volume hologram recording includes a binder polymer (A), a photo-induced cationically polymerizable compound (B), a photoinitiator (C), and a sensitizing dye (D), in which the binder polymer (A) is a polymer containing naphthalene rings and having a weight-average molecular weight of 1×10⁴ to 100×10⁴. A method produces a photosensitive composition (II) for volume hologram recording by mixing a binder polymer (A′), a photo-induced cationically polymerizable compound (B′), a photoinitiator (C′), and a sensitizing dye (D′), in which the photo-induced cationically polymerizable compound (B′) has been subjected to a heating treatment at a temperature equal to or lower than the boiling point of the compound (B′).

### TECHNICAL FIELD

The present invention relates to a photosensitive composition for volume hologram recording, used for the formation of volume holograms; a method for producing a volume hologram recording medium using the photosensitive composition for volume hologram recording; and a cured article obtained from the photosensitive composition for volume hologram recording through photo-induced cationic curing.

The present invention also relates to a production method for a photosensitive composition for volume hologram recording, which composition is used for the formation of volume holograms; a photosensitive composition for volume hologram recording obtained by the production method; a method for producing a volume hologram recording medium using the photosensitive composition for volume hologram recording; and a cured article obtained from the photosensitive composition for volume hologram recording through photo-induced cationic curing.

### BACKGROUND ART

Volume holograms are widely used typically in design, security, and optical element applications, because they can render an image three-dimensionally, have high diffraction efficiency and wavelength selectivity, and require advanced production techniques. Volume holograms are prepared by allowing object light and reference light, which are highly coherent and have the same wavelength, to interfere with each other and allowing the coherent light to enter a volume hologram recording material to record, as interference fringes, three-dimensional information regarding the object in the material. The interference fringes are recorded as refractive index modulation corresponding to the bright and dark parts of the coherent light. In recent production of volume holograms, attention has been directed to dry-type photosensitive compositions for volume hologram recording which eliminate the need to perform wet development and allow mass production.

Japanese Patent No. 2849021 discloses a volume holographic composition which shows high refractive index modulation and has excellent transparency. The material system mainly contains a monomer having a diarylfluorene skeleton as a radically polymerizable compound with a high refractive index; a cationically polymerizable compound; and a binder resin. The holographic photosensitive composition, however, significantly shrinks upon polymerization, which impedes the application of the photosensitive composition to optical elements and storage devices requiring dimensional stability, because the composition contains a photo-induced radically polymerizable group represented by acrylate or methacrylate group as a photo-polymerizable functional group.

Japanese Patent No. 3075082 discloses a composition including a fluorene derivative oligomer having glycidyl groups, as a cationically polymerizable compound with a high refractive index; a polymerizable monomer having a refractive index different from that of the oligomer; a photoinitiator; and a sensitizer. The material system gives a holographic photosensitive recording medium which has a higher refractive index, thereby shows enhanced refractive index modulation, and excels in transparency and thermal stability, because the epoxy oligomer forms a crosslinked structure through cationic polymerization. The holographic photosensitive composition, however, is problematic in sensitivity, because the fluorene derivative oligomer having such glycidyl groups shows low reactivity, although the composition including epoxy group as cationically polymerizable group less shrinks upon photo-induced radical polymerization.

Japanese Patent No. 4142396 discloses a composition including a diarylfluorene derivative oligomer having oxetanyl groups, as a cationically polymerizable compound with a high refractive index; a binder resin; a photoinitiator; and a sensitizing dye. The material system forms a crosslinked structure through cationic polymerization using the high reactivity of the oxetanyl groups and thereby gives a holographic photosensitive recording medium which shows less shrinkage on curing and excels in transparency and thermal stability. Even this holographic photosensitive composition, however, is not always satisfactorily typically in volume change between before and after photo-curing and in polymerization reactivity.

### CITATION LIST

### Patent Literature

PTL 1: Japanese Patent No. 2849021
PTL 2: Japanese Patent No. 3075082
PTL 3: Japanese Patent No. 4142396

### SUMMARY OF INVENTION

### Technical Problem

An object of the present invention is to provide a photosensitive composition for volume hologram recording which exhibits superior refractive-index modulability, has high polymerization reactivity, and shows very small volume shrinkage; a simple and efficient method for producing a volume hologram recording medium using the photosensitive composition for volume hologram recording; and a cured article obtained from the photosensitive resin composition for volume hologram recording.

Another object of the present invention is to provide a method for simply and efficiently producing a photosensitive composition for volume hologram recording, which exhibits superior refractive-index modulability, shows very small volume shrinkage, and has high diffraction efficiency; a photosensitive composition for volume hologram recording obtained by the method; a simple and efficient method for producing a volume hologram recording medium using the photosensitive composition for volume hologram recording; and a cured article obtained from the photosensitive resin composition for volume hologram recording.

### Solution to Problem

After intensive investigations to achieve the objects, the present inventors have found that, in a photosensitive composition for volume hologram recording containing a binder polymer, a photo-induced cationically polymerizable compound, a photoinitiator, and a sensitizing dye, the use of a polymer having a naphthalene ring as the binder polymer helps the photosensitive composition to have a high reactivity in photo-induced cationic polymerization, to show very small volume change between before and after photo-curing, and to exhibit superior refractive-index modulability. The present invention has been made based on these findings.

Specifically, the present invention provides, in an aspect, a photosensitive composition (I) for volume hologram recording, which includes a binder polymer (A); a photo-induced cationically polymerizable compound (B); a photoinitiator (C); and a sensitizing dye (D), in which the binder polymer (A) is a polymer containing naphthalene rings and having a weight-average molecular weight of 1×10⁴ to 100×10⁴.

The photo-induced cationically polymerizable compound (B) is preferably a compound intramolecularly having one or more of at least one cationically polymerizable group selected from the group consisting of epoxy group, vinyl ether group, and oxetanyl group.

In the photosensitive composition (I) for volume hologram recording, the binder polymer (A) preferably has a refractive index higher than the refractive index of the photo-induced cationically polymerizable compound (B) with a difference between the two refractive indices of from 0.001 to 0.4.

The photosensitive composition preferably shows a percentage of volume shrinkage of 1% or less after a hologram recording with reference to the volume before the hologram recording.

The present invention provides, in another embodiment, a method for producing a volume hologram recording medium, the method including the step of applying the photosensitive composition (I) for volume hologram recording to a base or substrate to form a volume holographic material layer thereon.

The method for producing a volume hologram recording medium may further includes the step of covering the volume holographic material layer after or during the formation thereof with a second base or substrate, the second base or substrate including the same material as that of the base or substrate to which the photosensitive composition (I) for volume hologram recording has been applied. The method may include the steps of applying the photosensitive composition (I) for volume hologram recording to a first base or substrate so as to give a volume holographic material layer having a thickness of 10 to 2000 μm; covering the coated layer with a second base or substrate to give a laminate, the second base or substrate including the same material as that of the first base or substrate; sealing the periphery of the laminate; and aging the sealed laminate for a given time.

The present invention further provides, in yet another embodiment, a cured article derived from the photosensitive composition (I) for volume hologram recording through photo-induced cationic curing.

In addition, the present inventors have found that, when a binder polymer, a photo-induced cationically polymerizable compound, a photoinitiator, and a sensitizing dye are mixed to give a photosensitive composition for volume hologram recording, the use of the photo-induced cationically polymerizable compound which has been subjected to a heating treatment at a temperature equal to or lower than its boiling point allows simple and efficient production of a photosensitive composition (II) for volume hologram recording, which exhibits superior refractive-index modulability, shows very small volume shrinkage, and has high diffraction efficiency. The present invention has been made also based on these findings.

Specifically, the present invention also provides, in another aspect, a method for producing a photosensitive composition (II) for volume hologram recording, the method including the step of mixing a binder polymer (A′), a photo-induced cationically polymerizable compound (B′), a photoinitiator (C′), and a sensitizing dye (D′) to give the photosensitive composition for volume hologram recording, in which the photo-induced cationically polymerizable compound (B′) has been previously subjected to a heating treatment at a temperature equal to or lower than the boiling point of the compound (B′).

The photo-induced cationically polymerizable compound (B′) is preferably a compound intramolecularly having one or more of at least one cationically polymerizable group selected from the group consisting of epoxy group, vinyl ether group, and oxetanyl group.

The binder polymer (A′) preferably has a refractive index higher than the refractive index of the photo-induced cationically polymerizable compound (B′) with a difference between the two refractive indices of from 0.001 to 0.5.

The present invention also provides a photosensitive composition (II) for volume hologram recording, as a product produced by the production method.

The photosensitive composition (II) for volume hologram recording preferably shows a percentage of volume shrinkage of 1% or less after a hologram recording with reference to the volume before the hologram recording.

The present invention also provides, in another embodiment, a method for producing a volume hologram recording medium, the method including the step of applying the photosensitive composition (II) for volume hologram recording to a base or substrate to form a volume holographic material layer thereon.

This method for producing a volume hologram recording medium may further include the step of covering the volume holographic material layer after or during the formation thereof with a second base or substrate, the second base or substrate including the same material as that of the base or substrate to which the photosensitive composition (II) for volume hologram recording has been applied. The method may include the steps of applying the photosensitive composition (II) for volume hologram recording to a first base or substrate so as to give a volume holographic material layer having a thickness of 10 to 2000 μm; covering the coated layer with a second base or substrate to give a laminate, the second base or substrate including the same material as that of the first baser or substrate; sealing the periphery of the laminate; and aging the sealed laminate for a given time.

In addition, the present invention provides a cured article derived from the photosensitive composition (II) for volume hologram recording through photo-induced cationic curing.

### Advantageous Effects of Invention

The photosensitive composition (I) for volume hologram recording according to the present invention exhibits superior refractive-index modulability, has high polymerization reactivity, shows very small volume shrinkage, and thereby gives holograms excellent typically in diffraction efficiency and reproducibility. The method for producing a volume hologram recording medium using the photosensitive composition (I) for volume hologram recording according to the present invention allows simple and efficient production of volume hologram recording media which excel in holographic properties such as diffraction efficiency.

The method for producing a photosensitive composition (II) for volume hologram recording according to the present invention allows simple and efficient production of the photosensitive composition (II) for volume hologram recording which exhibits superior refractive-index modulability, shows very small volume shrinkage, and exhibits high diffraction efficiency. The method therefore allows production of holograms which excel typically in diffraction efficiency and reproducibility. The method for producing a volume hologram recording medium using the photosensitive composition (II) for volume hologram recording according to the present invention allows simple and efficient production of volume hologram recording media which excel in holographic properties such as diffraction efficiency.

### BRIEF DESCRIPTION OF DRAWINGS

FIG. 1 is a schematic diagram showing an optical system used for the determination of diffraction efficiency and shrinkage percentage in working examples and comparative examples.

FIG. 2 is an explanatory drawing showing how to determine the shrinkage percentage in the working examples and comparative examples.

### DESCRIPTION OF EMBODIMENTS

The photosensitive composition (I) for volume hologram recording according to the present invention includes a binder polymer (A), a photo-induced cationically polymerizable compound (B), a photoinitiator (C), and a sensitizing dye (D).

[Binder Polymer (A)]

The photosensitive composition (I) for volume hologram recording according to the present invention uses, as the binder polymer (A), a polymer containing naphthalene rings and having a weight-average molecular weight of 1×10⁴ to 100×10⁴. The binder polymer, as containing naphthalene rings, can have a large difference in refractive index from the photo-induced cationically polymerizable compound (B) serving as a monomer. Each of different binder polymers (A) may be used alone or in combination.

Exemplary polymers having naphthalene rings include homo- or co-polymers of monomers having a naphthalene ring; and copolymers between a monomer having a naphthalene ring and a monomer having no naphthalene ring.

Exemplary monomers having a naphthalene ring include 1-vinylnaphthalene; 2-vinylnaphthalene; and (meth)acrylic esters having a naphthalene ring, such as 1-naphthyl (meth)acrylates and 2-naphthyl(meth)acrylates. Of these, 1-vinylnaphthalene and 2-vinylnaphthalene are preferred.

Exemplary monomers having no naphthalene ring include styrenic monomers such as styrene, α-methylstyrene, and vinyltoluene; (meth)acrylic esters including alkyl (meth)acrylates such as methyl (meth)acrylates, ethyl (meth)acrylates, and butyl (meth)acrylates, aryl (meth)acrylates [excluding naphthyl(meth)acrylates] such as phenyl(meth)acrylates, aralkyl(meth)acrylates such as benzyl(meth)acrylates, and cycloalkyl(meth)acrylates such as cyclohexyl(meth)acrylates; cyano-containing monomers such as (meth)acrylonitriles; (meth)acrylamides; monomers containing a carboxyl group or acid anhydride group, such as (meth)acrylic acids and maleic anhydride; vinyl chloride; vinyl esters such as vinyl acetate; olefins such as ethylene, propylene, and isobutene; and conjugated dienes such as butadiene and isoprene.

The amount of constitutional repeating units having a naphthalene ring in the naphthalene-ring-containing polymer is typically 30 percent by weight or more, preferably 50 percent by weight or more, and more preferably 80 percent by weight or more, based on the total amount of repeating units constituting the polymer.

Representative examples of the polymer containing naphthalene rings [binder polymer (A)] include poly-1-vinylnaphthalenes, poly-2-vinylnaphthalenes, and copolymers between any of the vinylnaphthalenes and a (meth)acrylic ester [e.g., alkyl(meth)acrylates such as methyl methacrylate].

The binder polymer (A) has a weight-average molecular weight of 1×10⁴ to 100×10⁴, and preferably about 4×10⁴ to about 30×10⁴.

The binder polymer (A) preferably has a refractive index higher than that of the photo-induced cationically polymerizable compound (B). The difference in refractive index between the binder polymer (A) and the photo-induced cationically polymerizable compound (B) is preferably, for example, from 0.001 to 0.4, and more preferably from 0.1 to 0.3.

The binder polymer(s) (A) is used in the photosensitive composition for volume hologram recording in an amount of typically 10 to 200 parts by weight and preferably 30 to 100 parts by weight per 100 parts by weight of the total amount of the photo-induced cationically polymerizable compound(s) (B).

[Photo-Induced Cationically Polymerizable Compound (B)]

The photo-induced cationically polymerizable compound (B) is not limited, as long as being at least one compound having a photo-induced cationically polymerizable group, but is preferably a compound intramolecularly having at least one cationically polymerizable group selected from the group consisting of epoxy group, vinyl ether group, and oxetanyl group. The compound may have one or multiplicity of the cationically polymerizable group per molecule. Each of different photo-induced cationically polymerizable compounds (B) may be used alone or in combination.

Exemplary compounds containing an epoxy group (epoxy compounds) include alicyclic epoxy resins intramolecularly having cyclic aliphatic groups and epoxy groups; and epoxy resins intramolecularly having glycidyl groups. Among them, alicyclic epoxy resins are preferred, of which more preferred are compounds whose epoxy group (oxirane ring) is formed as including two adjacent carbon atoms constituting the cyclic aliphatic group. The epoxy-containing compound may be whichever of a monofunctional epoxy compound and a multifunctional epoxy compound, of which a multifunctional epoxy compound is preferred. Each of different epoxy-containing compounds may be used alone or in combination.

Exemplary alicyclic epoxy resins include 3,4,3′,4′-diepoxybicyclohexyl, bis(3,4-epoxycyclohexyl) adipate, 3,4-epoxycyclohexylmethyl 3′,4′-epoxycyclohexanecarboxylate, (3,4-epoxy-6-methylcyclohexyl)methyl-3′,4′-epoxy-6-methylcyclohexanecarboxylate, ethylene 1,2-bis(3,4-epoxycyclohexanecarboxylic acid) ester, 3,4-epoxycyclohexylmethyl alcohol, and 3,4-epoxycyclohexylethyltrimethoxysilane. Exemplary commercial products of alicyclic epoxy resins usable herein include CELLOXIDE 2000, CELLOXIDE 2021, CELLOXIDE 3000, and EHPE 3150 each supplied by Daicel Chemical Industries, Ltd.; EPOMIK VG-3101 supplied by Mitsui Chemicals Inc.; E-1031S supplied by Yuka Shell Epoxy K.K.; TETRAD-X and TETRAD-C each supplied by Mitsubishi Gas Chemical Company, Inc.; and EPB-13 and EPB-27 each supplied by Nippon Soda Co., Ltd.

The vinyl-ether-containing compounds (vinyl ether compounds) are not limited, as long as being compounds containing a vinyl ether group and may be whichever of monofunctional vinyl ether compounds and multifunctional vinyl ether compounds, of which multifunctional vinyl ether compounds are preferred. Each of different vinyl-ether-containing compounds may be used alone or in combination.

Representative examples of compounds containing a vinyl ether group include cyclic ether-type vinyl ethers (vinyl ethers containing a cyclic ether group such as oxirane ring, oxetane ring, or oxolane ring) such as isosorbide divinyl ether and oxynorbornene divinyl ether; aryl vinyl ethers such as phenyl vinyl ether; alkyl vinyl ethers such as n-butyl vinyl ether and octyl vinyl ether; cycloalkyl vinyl ethers such as cyclohexyl vinyl ether; and multifunctional vinyl ethers such as hydroquinone divinyl ether, 1,4-butanediol divinyl ether, cyclohexane divinyl ether, and cyclohexanedimethanol divinyl ether. Exemplary compounds containing a vinyl ether group usable herein further include 2-hydroxyethyl vinyl ether (HEVE), diethylene glycol monovinyl ether (DEGV), 2-hydroxybutyl vinyl ether (HBVE), and triethylene glycol divinyl ether each available from Maruzen Petrochemical Co., Ltd., and also include vinyl ether compounds having one or more substituents such as alkyl groups and allyl groups at the alpha position and/or beta position.

The compounds containing an oxetanyl group (oxetane compounds) are not limited, as long as being compounds containing an oxetanyl group, and may be whichever of monofunctional oxetane compounds and multifunctional oxetane compounds, but multifunctional oxetane compounds are preferred. Each of different oxetanyl-containing compounds may be used alone or in combination.

Representative examples of oxetanyl-containing compounds include 3,3-dimethanol divinyl ether oxetane having an oxetanyl group and vinyl ether groups; and 3-ethyl-3-(phenoxymethyl)oxetane (PDX), di[1-ethyl(3-oxetanyl)]methyl ether (DOX), 3-ethyl-3-(2-ethylhexyloxymethyl)oxetane (EHOX), 3-ethyl-3-{[3-(triethoxysilyl)propoxy]methyl}oxetane (TESOX), oxetanylsilsesquioxane (OX-SQ), and phenol novolak oxetane (PNOX-1009) each available from Toagosei Co., Ltd.

The photo-induced cationically polymerizable compound (B) is preferably a combination of at least one epoxy compound and at least one compound selected from the group consisting of vinyl ether compounds and oxetane compounds, from the viewpoint of providing higher polymerization reactivity. In the combination use, the molar ratio of the at least one epoxy compound to the at least one compound selected from the group consisting of vinyl ether compounds and oxetane compounds is, for example, from 5:95 to 98:2, preferably from 20:80 to 95:5, more preferably from 50:50 to 95:5, and particularly preferably from 70:30 to 95:5.

[Photoinitiator (C)]

The photoinitiator (photopolymerization initiator) (C) is not limited, as long as being a compound that activates photo-induced cationic polymerization. Exemplary photoinitiators include aromatic diazonium salts, aromatic iodonium salts, aromatic sulfonium salts, aromatic phosphonium salts, and mixed-ligand metal salts such as (η6-benzene) (η5-cyclopentadienyl)iron(II) and silanol-aluminum complex. Each of different photoinitiators (C) may be used alone or in combination.

The photoinitiator(s) (C) may be used in an amount of typically 0.1 to 30 parts by weight, and preferably 0.5 to 20 parts by weight, per 100 parts by weight of the total amount of the photo-induced cationically polymerizable compound(s) (B). The photoinitiator (C) is preferably one that will be decomposed into a substance having no reactivity after hologram recording, from the viewpoint of stabilizing the recorded hologram.

[Sensitizing Dye (D)]

The sensitizing dye (D) is not limited, as long as being one that sensitizes the photoinitiator (C), and includes any of known sensitizing dyes. Exemplary sensitizing dyes (D) include thiopyrylium salt dyes, melocyanine dyes, quinoline dyes, styrylquinoline dyes, ketocoumarin dyes, thioxanthene dyes, xanthene dyes, oxonol dyes, cyanine dyes, rhodamine dyes, and pyrylium salt dyes. The sensitizing dye (D), if being a visible light sensitizing dye and used in optical elements and other applications requiring high transparency, is preferably one that will be decomposed into a colorless transparent substance in a downstream process from hologram recording, such as heating or ultraviolet ray irradiation. Each of different sensitizing dyes (D) may be used alone or in combination.

Sensitizing dye(s) is used in an amount of typically 0.01 to 20 parts by weight, and preferably 0.01 to 10 parts by weight, per 100 parts by weight of the total amount of the photo-induced cationically polymerizable compound(s) (B).

[Solvent]

The photosensitive composition (I) for volume hologram recording according to the present invention may further contain a solvent for higher coatability. Exemplary solvents include ketones such as acetone, methyl ethyl ketone, methyl isobutyl ketone, and cyclohexanone; aromatic hydrocarbons such as benzene, toluene, and xylenes; halogenated aromatic hydrocarbons such as chlorobenzene; ethers (cyclic ethers and chain ethers) such as tetrahydrofuran, 1,4-dioxane, and diisopropyl ether; esters such as methyl cellosolve (ethylene glycol monomethyl ether), ethyl cellosolve, methyl cellosolve acetate, ethyl cellosolve acetate, ethyl acetate, and butyl acetate; halogenated aliphatic hydrocarbons such as 1,2-dichloroethane, dichloromethane, and chloroform; alcohols such as methanol, ethanol, and isopropanol; and mixtures of these solvents.

Where necessary, the photosensitive composition (I) for volume hologram recording may further contain any of various additives. Customary additives may be used herein.

The photosensitive composition (I) for volume hologram recording preferably has a percentage of volume shrinkage of 1% or less after a hologram recording with reference to the volume before the hologram recording. Specifically, the photosensitive composition preferably has a percentage of volume shrinkage between before and after curing of 1% or less.

[Production of Volume Holographic Recording Media]

The method for producing a volume hologram recording medium according to the present invention includes the step of applying the photosensitive composition (I) for volume hologram recording to a base or substrate (a first base or substrate) to form a volume holographic material layer thereon. The photosensitive composition (I) for volume hologram recording, when contains a solvent and is applied to the base or substrate, may be dried to form the volume holographic material layer.

The base or substrate, to which the photosensitive composition (I) for volume hologram recording (coating composition) is applied, is not limited, as long as having transparency, and examples thereof include plastic films (including sheets) such as polyethylene films, polypropylene films, poly(ethylene fluoride) films, poly(vinylidene fluoride) films, poly(vinyl chloride) films, poly(vinylidene chloride) films, poly(methyl methacrylate) films, poly(ether sulfone) films, poly(ether ketone) films, polyamide films, copoly(tetrafluoroethylene-perfluoroalkyl vinyl ether) films, poly(ethylene terephthalate) (PET) films and other polyester films, polyimide films, polycarbonate films, COP films (films of cycloolefin polymers such as “TOPAS” supplied by Daicel Chemical Industries, Ltd.; “ZEONEX” supplied by ZEON CORPORATION; and “ARTON” supplied by JSR); and glass plates.

The base or substrate has a thickness of typically 2 to 2000 μm, and preferably 10 to 1000 μm.

When the photosensitive composition (I) for volume hologram recording (coating composition) has a low viscosity, the coating composition is placed between two plies of a base or substrate such as a glass plate, and the periphery of the two glass plates is sealed with a suitable sealing material so as to prevent the coating composition from flowing out of the surface of the base or substrate. Thus, a photosensitive medium for volume hologram recording is provided. Exemplary sealing materials include epoxy or acrylic thermosetting resins, and photo-curable resins. Where necessary, spacers may be used.

The application of the coating composition to the base or substrate may be performed through a known procedure such as coating with a spin coater, coating with a gravure coater, coating with a comma coater, coating with a bar coater, or one-drop filling.

The mass of coating of the coating composition is preferably such that the resulting volume holographic material layer has a thickness of typically 1 to 2000 μm, and preferably 10 to 1000 μm.

When the dried volume holographic material layer shows tackiness, it may be covered by any of the above-exemplified bases or substrates, as a protective film. In this case, a surface of the protective film (covering material) to be in contact with the volume holographic material layer may have been subjected to a release treatment so as to be easily peeled off later on.

In the production method according to the present invention, the volume holographic material layer after or during its formation may be covered by a second base or substrate, which second base or substrate is composed of the same material as that of the first base or substrate to which the photosensitive composition (I) for volume hologram recording is applied. The second base or substrate is preferably one having transparency, and examples thereof include those exemplified as the first base or substrate to which the photosensitive composition (I) for volume hologram recording is applied. Typically, when the photosensitive composition (I) for volume hologram recording is applied to a glass plate as the base or substrate, the volume holographic material layer after or during its formation may be covered by another ply of glass plate. Likewise, when the photosensitive composition (I) for volume hologram recording is applied to a polyethylene terephthalate (PET) film as the base or substrate, the volume holographic material layer after or during its formation may be covered by another ply of PET film.

In a preferred embodiment of the production method according to the present invention, a volume hologram recording medium is produced by applying the photosensitive composition (I) for volume hologram recording to a first base or substrate so as to give a volume holographic material layer having a thickness of 10 to 2000 μm; drying the volume holographic material layer as needed; covering the coated layer (during the formation of the volume hologram layer) with a second base or substrate to give a laminate, the second base or substrate including the same material as that of the first base or substrate; sealing the periphery of the laminate; and aging the sealed laminate for a given time to give the volume holographic material layer.

Where necessary, one or more spacers having a thickness of 10 to 2000 μm may be arranged in a frame form on the peripheral surface of the first base or substrate to which the photosensitive composition (I) for volume hologram recording is applied.

The second base or substrate to cover the coated layer is preferably one having transparency, and examples thereof include those exemplified as the first base or substrate to which the photosensitive composition (I) for volume hologram recording is applied.

The aging is performed at temperatures of typically about 0° C. to 50° C., and preferably about 10° C. to 40° C. The aging can be performed at room temperature. Although not critical, the aging time is generally about 0.1 to 48 hours, preferably about 0.2 to 10 hours, and more preferably about 0.5 to 5 hours. The aging is preferably performed under light-shielding conditions. The aging process allows the volume hologram recording layer to be smooth and to have stable holographic properties.

The way to record a hologram on the volume hologram recording medium according to the present invention is not limited and may employ any known process. Exemplary processes include a contact exposure process in which a master plate (original plate) is brought into intimate contact with the hologram recording material layer of the volume hologram recording medium, and a radiation such as visible light or an iodizing radiation such as ultraviolet ray or electron beams is applied from the surface of the transparent base film to perform interference exposure to record a volume hologram; a single-beam interference process in which the volume holographic material layer of the medium is arranged between two plies of glass or film, and a laser beam is applied through the surface of the medium to the master plate to record a volume hologram by the interference between the reflected laser beam from the master plate and the incident laser beam; a two-beam interference process in which laser beams are divided into two directions, of which one is applied directly to the photosensitive material and the other is applied once to the substance having information to be recorded and passes through the substance, and the resulting light (information light) is then applied to the photosensitive material; and a collinear process in which information light and reference light are applied coaxially.

The hologram recording may be performed using visible laser beams such as laser beams from argon ion laser (458 nm, 488 nm, or 514.5 nm), krypton ion laser (647.1 nm), helium-neon ion laser (633 nm), and semiconductor laser (405 nm or 532 nm).

For accelerating the refractive index modulation and for completing the polymerization reaction, the medium after interference exposure may be subjected to a suitable treatment such as heating or whole image exposure with an ultraviolet ray.

The resulting article in which the hologram has been recorded corresponds to a cured article obtained through photo-curing of the photosensitive composition (I) for volume hologram recording.

A recording mechanism of a hologram herein using the photosensitive composition (I) for volume hologram recording will be described below. A film layer (volume holographic material layer) of the photosensitive composition (I) for volume hologram recording is subjected to interference exposure with laser beams, whereby cationic polymerization starts in portions exposed to a high-intensity light to cause concentration gradient of the photo-induced cationically polymerizable compound (B), and the photo-induced cationically polymerizable compound (B) diffuses and migrates from portions exposed to a low-intensity light to the portions exposed to the high-intensity light. This causes the difference in density of the photo-induced cationically polymerizable compound (B) corresponding to the difference in light intensity, resulting in the difference in refractive index. In addition, the difference in refractive index between the photo-induced cationically polymerizable compound (B) and the binder polymer (A) allows recording of a hologram. After recording, the medium may be subjected to fixing through exposure and/or a heating treatment.

The heating treatment for recording may be performed at a temperature around the glass transition temperature of the binder polymer (A). This accelerates the migration of the photo-induced cationically polymerizable compound (B) and increases the magnitude of refractive index modulation.

The method for producing a photosensitive composition (II) for volume hologram recording according to another embodiment of the present invention includes the step of mixing a binder polymer (A′), a photo-induced cationically polymerizable compound (B′), a photoinitiator (C′), and a sensitizing dye (D′) to give a photosensitive composition for volume hologram recording, in which the photo-induced cationically polymerizable compound (B′) has been previously subjected to a heating treatment at a temperature equal to or lower than the boiling point of the compound (B′).

[Binder Polymer (A′)]

Exemplary binder polymers (A′) include poly(meth)acrylic esters or partially hydrolyzed products thereof, poly(vinyl acetate)s or hydrolyzed products thereof, poly(vinyl alcohol)s or partially acetalized products thereof, triacetylcellulose, polyisoprenes, polybutadienes, polychloroprenes, poly(vinyl chloride)ₛ, polyarylates, chlorinated polyethylenes, chlorinated polypropylenes, poly(N-vinylcarbazol)s or derivatives thereof, and poly(N-pyrrolidone)s or derivatives thereof; polymers or copolymers of styrene or another monomer having a benzene ring, or of vinylnaphthalene or another monomer having a naphthalene ring (for example, polystyrenes, poly-1-vinylnaphthalenes, poly-2-vinylnaphthalenes, copolymers between vinylnaphthalene and acrylate, copolymers between styrene and maleic anhydride, or half-esters of them); copolymers containing, as a polymerizable component, at least one selected from the group consisting copolymerizable monomers such as acrylic acid, an acrylic ester, methacrylic acid, a methacrylic ester, acrylamide, acrylonitrile, ethylene, propylene, vinyl chloride, and vinyl acetate; and mixtures of these. Among them, polymers or copolymers of a monomer having a naphthalene ring are preferred.

The binder polymer (A′) has a weight-average molecular weight of typically about 1×10⁴ to 100×10⁴, and preferably about 4×10⁴ to 30×10⁴.

The binder polymer (A′) preferably has a refractive index higher than that of the photo-induced cationically polymerizable compound (B′). The binder polymer (A′) preferably has a difference in refractive index from the photo-induced cationically polymerizable compound (B′) of typically from 0.001 to 0.5, and especially preferably from 0.1 to 0.3. The use of the binder polymer (A′) having such characteristic properties allows further satisfactory holographic properties.

The binder polymer (A′) may be used in the photosensitive composition for volume hologram recording in an amount of typically 10 to 200 parts by weight, and preferably 30 to 100 parts by weight, per 100 parts by weight of the total amount of the photo-induced cationically polymerizable compound(s) (B′).

[Photo-Induced Cationically Polymerizable Compound (B′)]

Exemplary compounds as the photo-induced cationically polymerizable compound (B′), and, when they are used in combination, the proportions between the compounds are as with the exemplary compounds as the photo-induced cationically polymerizable compound (B) and the proportions between them upon combination use.

The photosensitive composition (II) for volume hologram recording according to the present invention uses the photo-induced cationically polymerizable compound (B′) which has been previously subjected to a heating treatment at a temperature equal to or lower than the boiling point of the compound (B′). The heating may be performed at a temperature of 80° C. or higher and equal to or lower than the boiling point (for example, a temperature from 80° C. to 150° C.), preferably at a temperature of 85° C. or higher and equal to or lower than the boiling point (for example, a temperature from 85° C. to 130° C.). Although not critical, the heating time is generally about 0.1 to 24 hours, preferably about 0.2 to 10 hours, and more preferably about 0.5 to 5 hours. The heating treatment may be performed in an air atmosphere or in an atmosphere of an inert gas such as nitrogen gas. It is preferably performed in an air atmosphere. The heating treatment may be performed under any conditions of normal atmospheric pressure, under reduced pressure, and under a pressure (under a load). The use of the photo-induced cationically polymerizable compound (B′) which has been subjected to a heating treatment at a temperature equal to or lower than the boiling point significantly improves holographic properties such as diffraction efficiency. This is probably because the heating treatment increases the compatibility or miscibility between monomers. Also in the production of the photosensitive composition (I) for volume hologram recording, the photo-induced cationically polymerizable compound (B) may have previously been subjected to a heating treatment at a temperature equal to or lower than the boiling point thereof.

[Photoinitiator (C′)]

Exemplary compounds as the photoinitiator (C′) are as with the compounds as the photoinitiator (C).

The photoinitiator (C′) is used in the photosensitive composition (II) for volume hologram recording in an amount of typically 0.1 to 30 parts by weight, and preferably 1 to 20 parts by weight, per 100 parts by weight of the total amount of the photo-induced cationically polymerizable compound(s) (B′). The photoinitiator (C′) is preferably one that will be decomposed into a substance having no reactivity after hologram recording, from the viewpoint of stabilizing the recorded hologram.

[Sensitizing Dye (D′)]

Exemplary compounds as the sensitizing dye (D′) and the amount thereof are as with the compounds as the sensitizing dye (D) and the amount thereof.

According to the method for producing a photosensitive composition (II) for volume hologram recording, the photosensitive composition (II) for volume hologram recording is produced by mixing the photo-induced cationically polymerizable compound (B′) which has been subjected to the heating treatment, the binder polymer (A′), the photoinitiator (C′), and the sensitizing dye (D′). The order of mixing the respective components is not critical; and the way to mix them is also not limited. Where necessary for higher coatability, a solvent may be used in the preparation of the photosensitive composition (II) for volume hologram recording. Independently, various additives may be added according to necessity. Customary additives may be used herein.

Exemplary solvents include ketones such as acetone, methylethyl ketone, methyl isobutyl ketone, and cyclohexanone; aromatic hydrocarbons such as benzene, toluene, and xylenes; halogenated aromatic hydrocarbons such as chlorobenzene; ethers (cyclic ethers and chain ethers) such as tetrahydrofuran, 1,4-dioxane, and diisopropyl ether; esters such as methyl cellosolve, ethyl cellosolve, methyl cellosolve acetate, ethyl cellosolve acetate, ethyl acetate, and butyl acetate; halogenated aliphatic hydrocarbons such as 1,2-dichloroethane, dichloromethane, and chloroform; alcohols such as methanol, ethanol, and isopropanol; and mixtures of them.

The resulting photosensitive composition (II) for volume hologram recording according to the present invention preferably has a percentage of volume shrinkage of 1% or less after a hologram recording with reference to the volume before the hologram recording. Specifically, the photosensitive composition preferably has a percentage of volume shrinkage between before and after curing of 1% or less.

[Production of Volume Holographic Recording Media]

The method for producing a volume hologram recording medium according to another embodiment of the present invention includes the step of applying the photosensitive composition (II) for volume hologram recording to a base or substrate to form a volume holographic material layer thereon. The photosensitive composition (II) for volume hologram recording, when contains a solvent and is applied to the base or substrate, may be dried to form the volume holographic material layer.

The method for producing a volume hologram recording medium including the step of applying the photosensitive composition (II) for volume hologram recording to a base or substrate to form a volume holographic material layer thereon is performed by the same procedure as the method for producing a volume hologram recording medium, including the step of applying the photosensitive composition (I) for volume hologram recording to a base or substrate to form a volume holographic material layer thereon, except for using the volume hologram recording composition (II) instead of the volume hologram recording composition (I).

A method for recording a hologram on the volume hologram recording medium prepared by applying the photosensitive composition (II) for volume hologram recording to a base or substrate to form a volume holographic material layer thereon is performed by the same procedure as the method for recording a hologram on the volume hologram recording medium prepared by applying the photosensitive composition (I) for volume hologram recording to a base or substrate to form a volume holographic material layer thereon.

The resulting article on which the hologram is recorded according to this method corresponds to a cured article obtained through photo-curing of the photosensitive composition (II) for volume hologram recording.

The mechanism for recording a hologram using the photosensitive composition (II) for volume hologram recording is the same as the mechanism for recording a hologram using the photosensitive composition (I) for volume hologram recording, except for using the photo-induced cationically polymerizable compound (B′) instead of the photo-induced cationically polymerizable compound (B), and using the binder polymer (A′) instead of the binder polymer (A).

### EXAMPLES

The present invention will be illustrated in further detail with reference to several working examples below. It should be noted, however, that these examples are never construed to limit the scope of the present invention.

(Optical System)

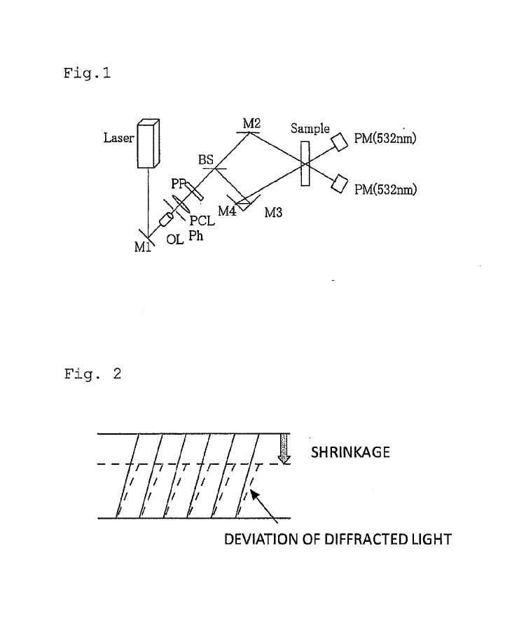

FIG. 1 shows a schematic diagram of the optical system used in the following experiments. A light source used herein was 532-nm semiconductor laser, and laser beams emitted therefrom passed through a mirror (M), spatial filters (OL and Ph), a planoconvex lens (PCL), and a phase plate (retardation plate) (PP) and were split into two beams by a beam splitter (BS). The two beams split by the BS were applied via mirrors to the sample at angles of 30 degrees and 30 degrees, respectively, and thereby interfered. The intensities of the diffracted light and transmitted light were respectively determined with power meters (PM: supplied by ADC Corporation).

The diffraction efficiency and shrinkage percentage were determined by the following methods.

(Diffraction Efficiency)

A hologram was recorded by the two-beam interference process, and the diffraction efficiency thereof was measured with the power meters. Two 532-nm semiconductor laser beams each with a diameter of 5 were applied at angles of 30 degrees, and the transmitted light and diffracted light were detected. The hologram recording medium was axially rotated at angles of from −5° to 5°, and the diffraction efficiency was calculated according to Equation (1) at a point where a maximum diffracted light intensity was achieved:

η=L₁/(L₀+L₁) (Equation 1)

wherein L₀ represents the transmitted light intensity; and L₁ represents the diffracted light intensity.

(Shrinkage Percentage)

A sample hologram recording medium was arranged as inclined at an angle of 10 degrees, and a hologram recording was performed at angles of recording light (information light) and reference light of 20 degrees and 40 degrees, respectively. The reference light was then applied at an incident angle of 40 degrees, and an angle (θ₁) at which a maximum diffraction efficiency was attained was detected. When the medium shows no shrinkage, the angle at which a maximum diffraction efficiency is attained is 40 degrees; but if the medium shrunk, the angle deviates from 40 degrees (FIG. 2). Likewise, the recording light alone was applied at an incident angle of 20 degrees, and an angle (O₂) at which the maximum diffraction efficiency was achieved was detected. Grating vectors (K₁ and K₂) of the recording medium in a thickness direction were determined from these angles according to the following Equations 2 and 3, and based on these, the shrinkage percentage was determined according to following Equation 4:

K₁=(2π/λ){(n²−sin ²θ₁′)−^{1/2})−(n²−sin ²θ₂′)^{1/2})} (Equation 2)

wherein λ represents the recording wavelength; n represents the refractive index of the recording layer; and θ₁′ and θ₂′ represent the incident angles of 40 degrees and 20 degrees, respectively, before recording,

K₂=(2π/λ){(n²−sin ²θ₁′)−^{1/2})−(n²−sin ²θ₂′)^{1/2})} (Equation 3)

wherein λ represents the recording wavelength; n represents the refractive index of the recording layer; and θ₁′ and θ₂′ represent the incident angles at which the diffraction efficiency attains maximum,

Shrinkage Percentage (%)=(K₁−K₂)/K₁×100 (Equation 4)

wherein K₁ represents the grating vector before recording; and K₂ represents the grating vector after recording.

### Example X-1

A photosensitive composition X-1 was prepared by dissolving 60 parts by weight of a poly-2-vinylnaphthalene (Mw=93,000) as a binder polymer (A), 100 parts by weight of a cationically polymerizable compound (B), 10 parts by weight of diphenyliodonium compound (trade name “PI 2074” supplied by Rhodia) as a photoinitiator (C), and 0.5 part by weight of a coumarin dye (trade name “NKX 1658” supplied by Hayashibara Biochemical Laboratories, Inc.) as a sensitizing dye (D) in 30 parts by weight of cyclohexanone. The cationically polymerizable compound (B) was a 7:1 (by mole) mixture of a bifunctional alicyclic epoxy compound (3,4,3′,4′-diepoxybicyclohexyl) and a bifunctional vinyl ether compound (oxynorbornene divinyl ether). The photosensitive composition X-1 was dropped onto a glass substrate, spread thereon with an applicator so as to give a layer with a thickness of 25 μm, and a PET film having a thickness of 50 μm was placed in a frame form on the peripheral surface of the glass substrate in such a manner as to avoid the contact with the photosensitive composition. Next, the coated layer was sandwiched between the glass substrate and another ply of glass substrate, aged at room temperature under light-shielding conditions for 1 hour, and yielded a hologram recording medium X-1 (having a thickness of the holographic material layer of 25 μm). The hologram recording medium X-1 was exposed to light from semiconductor laser (at 532 nm with an exposure energy of 300 mJ/cm²) using a two-beam optical system to record a hologram. As a result, the diffraction efficiency was 22%, and the shrinkage percentage was 0.4%.

### Example X-2

A photosensitive composition X-2 was prepared by dissolving 70 parts by weight of a poly-2-vinylnaphthalene (Mw=93,000) as a binder polymer (A), 100 parts by weight of a cationically polymerizable compound (B), 10 parts by weight of a diphenyliodonium compound (trade name “PI 2074” supplied by Rhodia) as a photoinitiator (C), and 0.5 part by weight of a coumarin dye (trade name “NKX 1658” supplied by Hayashibara Biochemical Laboratories, Inc.) as a sensitizing dye (D) in 280 parts by weight of cyclohexanone. The cationically polymerizable compound (B) was a 7:1 (by mole) mixture of a bifunctional alicyclic epoxy compound (3,4,3′,4′-diepoxybicyclohexyl) and a bifunctional vinyl ether compound (oxynorbornene divinyl ether). A hologram recording medium X-2 (having a thickness of the holographic material layer of 25 μm) was prepared by the procedure of Example X-1, except for dropping the photosensitive composition X-2 onto a glass substrate, spreading thereon using an applicator so as to have a dry thickness of 25 μm, and drying in an oven at 100° C. to remove the solvent thoroughly. Using this medium, a hologram recording was performed by the procedure of Example X-1. As a result, the diffraction efficiency was 35%, and the shrinkage percentage was −0.3%, indicating that the medium expanded.

### Example X-3

A photosensitive composition X-3 was prepared by dissolving 70 parts by weight of a poly-2-vinylnaphthalene (Mw=93,000) as a binder polymer (A), 100 parts by weight of a cationically polymerizable compound (B), 10 parts by weight of a diphenyliodonium compound (trade name “PI 2074” supplied by Rhodia) as a photoinitiator (C), and 0.5 part by weight of a coumarin dye (trade name “NKX 1658” supplied by Hayashibara Biochemical Laboratories, Inc.) as a sensitizing dye (D) in 280 parts by weight of cyclohexanone. The cationically polymerizable compound (B) was a 7:1 (by mole) mixture of a bifunctional alicyclic epoxy compound (3,4,3′,4′-diepoxybicyclohexyl) and a bifunctional vinyl ether compound (isosorbide divinyl ether). A hologram recording medium X-3 was prepared by the procedure of Example X-1, except for dropping the photosensitive composition X-3 onto a glass substrate, spreading thereon using an applicator so as to have a dry thickness of 25 μm, and drying in an oven at 100° C. to remove the solvent thoroughly. Using this medium, a hologram recording was performed by the procedure of Example X-1. As a result, the diffraction efficiency was 33%, and the shrinkage percentage was 0.2%.

### Example X-4

A photosensitive composition X-4 was prepared by dissolving 70 parts by weight of a poly-2-vinylnaphthalene (Mw=93,000) as a binder polymer (A), 100 parts by weight of a cationically polymerizable compound (B), 10 parts by weight of a diphenyliodonium compound (trade name “PI 2074” supplied by Rhodia) as a photoinitiator (C), and 0.5 part by weight of a coumarin dye (trade name “NKX 1658” supplied by Hayashibara Biochemical Laboratories, Inc.) as a sensitizing dye (D) in 280 parts by weight of cyclohexanone. The cationically polymerizable compound (B) was a 7:1 (by mole) mixture of a bifunctional alicyclic epoxy compound (3,4,3′,4′-diepoxybicyclohexyl) and a monofunctional vinyl ether compound (phenyl vinyl ether). A hologram recording medium X-4 was prepared by the procedure of Example X-1, except for dropping the photosensitive composition X-4 onto a glass substrate, spreading thereon using an applicator so as to have a dry thickness of 25 μm, and drying in an oven at 100° C. to remove the solvent thoroughly. Using this medium, a hologram recording was performed by the procedure of Example X-1. As a result, the diffraction efficiency was 28%, and the shrinkage percentage was 0.2%.

### Example X-5

A photosensitive composition X-5 was prepared by dissolving 70 parts by weight of a poly-2-vinylnaphthalene (Mw=93,000) as a binder polymer (A), 100 parts by weight of a cationically polymerizable compound (B), 10 parts by weight of a diphenyliodonium compound (trade name “PI 2074” supplied by Rhodia) as a photoinitiator (C), and 0.5 part by weight of a coumarin dye (trade name “NKX 1658” supplied by Hayashibara Biochemical Laboratories, Inc.) as a sensitizing dye (D) in 280 parts by weight of cyclohexanone. The cationically polymerizable compound (B) was a 2:1 (by mole) mixture of a bifunctional alicyclic epoxy compound (3,4,3′,4′-diepoxybicyclohexyl) and a bifunctional oxetane compound (di[1-ethyl(3-oxetanyl)]methyl ether, supplied by Toagosei Co., Ltd.). A hologram recording medium X-5 was prepared by the procedure of Example X-1, except for dropping the photosensitive composition X-5 onto a glass substrate, spreading thereon using an applicator so as to have a dry thickness of 25 μm, and drying in an oven at 100° C. to remove the solvent thoroughly. Using this medium, a hologram recording was performed by the procedure of Example X-1. As a result, the diffraction efficiency was 33%, and the shrinkage percentage was 0.8%.

### Example X-6

A photosensitive composition X-6 was prepared by dissolving 70 parts by weight of a poly-2-vinylnaphthalene (Mw=93,000) as a binder polymer (A), 100 parts by weight of a cationically polymerizable compound (B), 10 parts by weight of a diphenyliodonium compound (trade name “PI 2074” supplied by Rhodia) as a photoinitiator (C), and 0.5 part by weight of a coumarin dye (trade name “NKX 1658” supplied by Hayashibara Biochemical Laboratories, Inc.) as a sensitizing dye (D) in 280 parts by weight of cyclohexanone. The cationically polymerizable compound (B) was a 2:1 (by mole) mixture of a bifunctional alicyclic epoxy compound (3,4,3′,4′-diepoxybicyclohexyl) and a monofunctional oxetane compound (3-ethyl-3-(phenoxymethyl)oxetane, supplied by Toagosei Co., Ltd.). A hologram recording medium X-6 was prepared by the procedure of Example X-1, except for dropping the photosensitive composition X-6 onto a glass substrate, spreading thereon using an applicator so as to have a dry thickness of 25 μm, and drying in an oven at 100° C. to remove the solvent thoroughly. Using this medium, a hologram recording was performed by the procedure of Example X-1. As a result, the diffraction efficiency was 25%, and the shrinkage percentage was 0.8%.

### Example X-7

A photosensitive composition X-7 was prepared by dissolving 70 parts by weight of a poly-2-vinylnaphthalene (Mw=93,000) as a binder polymer (A), 100 parts by weight of a cationically polymerizable compound (B), 10 parts by weight of a diphenyliodonium compound (trade name “PI 2074” supplied by Rhodia) as a photoinitiator (C), and 0.5 part by weight of a coumarin dye (trade name “NKX 1658” supplied by Hayashibara Biochemical Laboratories, Inc.) as a sensitizing dye (D) in 280 parts by weight of cyclohexanone. The cationically polymerizable compound (B) was a 2:1 (by mole) mixture of a bifunctional alicyclic epoxy compound (3,4,3′,4′-diepoxybicyclohexyl) and a bifunctional vinyl ether-monofunctional oxetane compound (3,3-dimethanol divinyl ether oxetane). A hologram recording medium X-7 was prepared by the procedure of Example X-1, except for dropping the photosensitive composition X-7 onto a glass substrate, spreading thereon using an applicator so as to have a dry thickness of 25 μm, and drying in an oven at 100° C. to remove the solvent thoroughly. Using this medium, a hologram recording was performed by the procedure of Example X-1. As a result, the diffraction efficiency was 21%, and the shrinkage percentage was 0.9%.

### Example X-8

A photosensitive composition X-8 was prepared by dissolving 70 parts by weight of a poly-2-vinylnaphthalene (Mw=93,000) as a binder polymer (A), 100 parts by weight of a cationically polymerizable compound (B), 10 parts by weight of a diphenyliodonium compound (trade name “PI 2074” supplied by Rhodia) as a photoinitiator (C), and 0.5 part by weight of a coumarin dye (trade name “NKX 1658” supplied by Hayashibara Biochemical Laboratories, Inc.) as a sensitizing dye (D) in 280 parts by weight of cyclohexanone. The cationically polymerizable compound (B) was a 7:1 (by mole) mixture of a bifunctional alicyclic epoxy compound (3,4-epoxycyclohexylmethyl-3′,4′-epoxycyclohexanecarboxylate, trade name “CEL 2021P” (CELLOXIDE 2021P) supplied by Daicel Chemical Industries, Ltd.) and a bifunctional vinyl ether compound (oxynorbornene divinyl ether). A hologram recording medium X-8 was prepared by the procedure of Example X-1, except for dropping the photosensitive composition X-8 onto a glass substrate, spreading thereon using an applicator so as to have a dry thickness of 25 μm, and drying in an oven at 100° C. to remove the solvent thoroughly. Using this medium, a hologram recording was performed by the procedure of Example X-1. As a result, the diffraction efficiency was 16%, and the shrinkage percentage was 2.3%.

### Comparative Example X-1

A photosensitive composition X-9 was prepared by dissolving 70 parts by weight of a polystyrene as a binder polymer (A), 100 parts by weight of a cationically polymerizable compound (B), 10 parts by weight of a diphenyliodonium compound (trade name “PI 2074” supplied by Rhodia) as a photoinitiator (C), and 0.5 part by weight of a coumarin dye (trade name “NKX 1658” supplied by Hayashibara Biochemical Laboratories, Inc.) as a sensitizing dye (D) in 280 parts by weight of cyclohexanone. The cationically polymerizable compound (B) was a 7:1 (by mole) mixture of a bifunctional alicyclic epoxy compound (3,4,3′,4′-diepoxybicyclohexyl) and a bifunctional vinyl ether compound (oxynorbornene divinyl ether). A hologram recording medium X-9 was prepared by the procedure of Example X-1, except for dropping the photosensitive composition X-9 onto a glass substrate, spreading thereon using an applicator so as to have a dry thickness of 25 μm, and drying in an oven at 100° C. to remove the solvent thoroughly. Using this medium, a hologram recording was performed by the procedure of Example X-1. As a result, the diffraction efficiency was 18%, and the shrinkage percentage was 0.3%.

### Comparative Example X-2

A photosensitive composition X-10 was prepared by dissolving 70 parts by weight of a poly(methyl methacrylate) as a binder polymer (A), 100 parts by weight of a cationically polymerizable compound (B), 10 parts by weight of a diphenyliodonium compound (trade name “PI 2074” supplied by Rhodia) as a photoinitiator (C), and 0.5 part by weight of a coumarin dye (trade name “NKX 1658” supplied by Hayashibara Biochemical Laboratories, Inc.) as a sensitizing dye (D) in 280 parts by weight of cyclohexanone. The cationically polymerizable compound (B) was a 7:1 (by mole) mixture of a bifunctional alicyclic epoxy compound (3,4,3′,4′-diepoxybicyclohexyl) and a bifunctional vinyl ether compound (oxynorbornene divinyl ether). A hologram recording medium X-10 was prepared by the procedure of Example X-1, except for dropping the photosensitive composition X-10 onto a glass substrate, spreading thereon using an applicator so as to have a dry thickness of 25 μm, and drying in an oven at 100° C. to remove the solvent thoroughly. Using this medium, a hologram recording was performed by the procedure of Example X-1. As a result, the diffraction efficiency was 5%, and the shrinkage percentage was 0.2%.

### Comparative Example X-3

A photosensitive composition X-11 was prepared by dissolving 70 parts by weight of a poly(vinyl acetate) as a binder polymer (A), 100 parts by weight of a cationically polymerizable compound (B), 10 parts by weight of a diphenyliodonium compound (trade name “PI 2074” supplied by Rhodia) as a photoinitiator (C), and 0.5 part by weight of a coumarin dye (trade name “NKX 1658” supplied by Hayashibara Biochemical Laboratories, Inc.) as a sensitizing dye (D) in 280 parts by weight of cyclohexanone. The cationically polymerizable compound (B) was a 7:1 (by mole) mixture of a bifunctional alicyclic epoxy compound (3,4,3′,4′-diepoxybicyclohexyl) and a bifunctional vinyl ether compound (oxynorbornene divinyl ether). A hologram recording medium X-11 was prepared by the procedure of Example X-1, except for dropping the photosensitive composition X-11 onto a glass substrate, spreading thereon using an applicator so as to have a dry thickness of 25 μm, and drying in an oven at 100° C. to remove the solvent thoroughly. Using this medium, a hologram recording was performed by the procedure of Example X-1. As a result, the diffraction efficiency was 15%, and the shrinkage percentage was 0.4%.

### Comparative Example X-4

### Radical Polymerization System

A photosensitive composition X-12 was prepared by mixing 100 parts by weight of a 7:3 (by weight) mixture of pentaerythritol triacrylate and neopentyl glycol dimethacrylate as radically polymerizable monomers, 5 parts by weight of a diphenyliodonium compound (trade name “PI 2074” supplied by Rhodia), 0.15 part by weight of a coumarin dye (trade name “NKX 1658” supplied by Hayashibara Biochemical Laboratories, Inc.) as a sensitizing dye, and 20 parts by weight of diethyl sebacate as a plasticizer. Except for using the photosensitive composition X-12, a hologram recording was performed by the procedure of Example X-1. As a result, the diffraction efficiency was 30%, and the shrinkage percentage was 10.2%.

### Example Y-1

As a photo-induced cationically polymerizable compound (B′), a 7:1 (by mole) mixture of a bifunctional alicyclic epoxy compound (3,4,3′,4′-diepoxybicyclohexyl) and a bifunctional vinyl ether compound (oxynorbornene divinyl ether) was subjected to a heating treatment on an oil bath at 100° C. in an air atmosphere for 30 minutes. Next, a photosensitive composition Y-1 was prepared by dissolving 100 parts by weight of the heat-treated cationically polymerizable compound (B′), 60 parts by weight of a poly-2-vinylnaphthalene (Mw=93,000) as a binder polymer (A′), 10 parts by weight of a diphenyliodonium compound (trade name “PI 2074” supplied by Rhodia) as a photoinitiator (C′), and 0.5 part by weight of a coumarin dye (trade name “NKX 1658” supplied by Hayashibara Biochemical Laboratories, Inc.) as a sensitizing dye (D′) in 30 parts by weight of cyclohexanone. The photosensitive composition Y-1 was dropped onto a glass substrate, spread thereon using an applicator so as to have a film thickness of 50 μm, and a spacer film (PET) having a thickness of 50 μm was placed in a frame form on the peripheral surface of the glass substrate in such a manner as to avoid the contact with the photosensitive composition. Next, the coated layer was sandwiched between the glass substrate and another ply of glass substrate, aged at room temperature under light-shielding conditions for 1 hour, and thereby yielded a hologram recording medium Y-1 (having a thickness of the holographic material layer of 50 μm). The hologram recording medium Y-1 was exposed to light from semiconductor laser (at 532 nm with an exposure energy of 300 mJ/cm²) using a two-beam optical system to record a hologram. As a result, the diffraction efficiency was 30%, and the shrinkage percentage was 0.7%.

### Example Y-2

A hologram recording medium Y-2 was prepared by the procedure of Example Y-1, except for dropping the photosensitive composition Y-1 obtained from Example Y-1 onto a glass substrate, spreading thereon using an applicator so as to have a dry thickness of 50 μm, and drying at room temperature under light-shielding conditions for 20 hours. Using this medium, a hologram recording was performed by the procedure of Example Y-1. As a result, the diffraction efficiency was 45%, and the shrinkage percentage was 0.4%.

### Example Y-3

A hologram recording medium Y-3 was prepared by the procedure of Example Y-1, except for dropping the photosensitive composition Y-1 obtained from Example Y-1 onto a glass substrate, spreading thereon using an applicator so as to have a dry thickness of 300 μm, drying at room temperature under light-shielding conditions for 20 hours, and using a spacer film (PET) having a thickness of 300 μm. Using this medium, a hologram recording was performed by the procedure of Example Y-1. As a result, the diffraction efficiency was 20%, and the shrinkage percentage was 0.3%.

### Example Y-4

As a photo-induced cationically polymerizable compound (B′), a 7:1 (by mole) mixture of a bifunctional alicyclic epoxy compound (3,4,3′,4′-diepoxybicyclohexyl) and a bifunctional vinyl ether compound (isosorbide divinyl ether) was subjected to a heating treatment on an oil bath at 100° C. in an air atmosphere for 30 minutes. Next, a photosensitive composition Y-2 was prepared by dissolving 100 parts by weight of the heat-treated cationically polymerizable compound (B′), 60 parts by weight of a poly-2-vinylnaphthalene (Mw=93,000) as a binder polymer (A′), 10 parts by weight of a diphenyliodonium compound (trade name “PI 2074” supplied by Rhodia) as a photoinitiator (C′), and 0.5 part by weight of a coumarin dye (trade name “NKX 1658” supplied by Hayashibara Biochemical Laboratories, Inc.) as a sensitizing dye (D′) in 30 parts by weight of cyclohexanone. A hologram recording medium Y-4 was prepared by the procedure of Example Y-1, except for dropping the photosensitive composition Y-2 onto a glass substrate, spreading thereon using an applicator so as to have a dry thickness of 50 μm, and drying at room temperature under light-shielding conditions for 20 hours. Using this medium, a hologram recording was performed by the procedure of Example Y-1. As a result, the diffraction efficiency was 40%, and the shrinkage percentage was 0.4%.

### Example Y-5

As a photo-induced cationically polymerizable compound (B′), a 7:1 (by mole) mixture of a bifunctional alicyclic epoxy compound (3,4,3′,4′-diepoxybicyclohexyl) and a monofunctional vinyl ether compound (phenyl vinyl ether) was subjected to a heating treatment on an oil bath at 100° C. in an air atmosphere for 30 minutes. Next, a photosensitive composition Y-3 was prepared by dissolving 100 parts by weight of the heat-treated cationically polymerizable compound (B′), 60 parts by weight of a poly-2-vinylnaphthalene (Mw=93,000) as a binder polymer (A′), 10 parts by weight of a diphenyliodonium compound (trade name “PI 2074” supplied by Rhodia) as a photoinitiator (C′), and 0.5 part by weight of a coumarin dye (trade name “NKX 1658” supplied by Hayashibara Biochemical Laboratories, Inc.) as a sensitizing dye (D′) in 30 parts by weight of cyclohexanone. A hologram recording medium Y-5 was prepared by the procedure of Example Y-1, except for dropping the photosensitive composition Y-3 onto a glass substrate, spreading thereon using an applicator so as to have a dry thickness of 50 μm, and drying at room temperature under light-shielding conditions for 20 hours. Using this medium, a hologram recording was performed by the procedure of Example Y-1. As a result, the diffraction efficiency was 38%, and the shrinkage percentage was 0.3%.

### Example Y-6

As a photo-induced cationically polymerizable compound (B′), a 2:1 (by mole) mixture of a bifunctional alicyclic epoxy compound (3,4,3′,4′-diepoxybicyclohexyl) and a bifunctional oxetane compound (di[1-ethyl(3-oxetanyl)]methyl ether, supplied by Toagosei Co., Ltd.) was subjected to a heating treatment on an oil bath at 100° C. in an air atmosphere for 30 minutes. Next, a photosensitive composition Y-4 was prepared by dissolving 100 parts by weight of the heat-treated cationically polymerizable compound (B′), 60 parts by weight of a poly-2-vinylnaphthalene (Mw=93,000) as a binder polymer (A′), 10 parts by weight of a diphenyliodonium compound (trade name “PI 2074” supplied by Rhodia) as a photoinitiator (C′), and 0.5 part by weight of a coumarin dye (trade name “NKX 1658” supplied by Hayashibara Biochemical Laboratories, Inc.) as a sensitizing dye (D′) in 30 parts by weight of cyclohexanone. A hologram recording medium Y-6 was prepared by the procedure of Example Y-1, except for dropping the photosensitive composition Y-4 onto a glass substrate, spreading thereon using an applicator so as to have a dry thickness of 50 μm, and drying at room temperature under light-shielding conditions for 20 hours. Using this medium, a hologram recording was performed by the procedure of Example Y-1. As a result, the diffraction efficiency was 35%, and the shrinkage percentage was 0.7%.

### Example Y-7

As a photo-induced cationically polymerizable compound (B′), a 2:1 (by mole) mixture of a bifunctional alicyclic epoxy compound (3,4,3′,4′-diepoxybicyclohexyl) and a monofunctional oxetane compound (3-ethyl-3-(phenoxymethyl)oxetane, supplied by Toagosei Co., Ltd.) was subjected to a heating treatment on an oil bath at 100° C. in an air atmosphere for 30 minutes. Next, a photosensitive composition Y-5 was prepared by dissolving 100 parts by weight of the heat-treated cationically polymerizable compound (B′), 60 parts by weight of a poly-2-vinylnaphthalene (Mw=93,000) as a binder polymer (A′), 10 parts by weight of a diphenyliodonium compound (trade name “PI 2074” supplied by Rhodia) as a photoinitiator (C′), and 0.5 part by weight of a coumarin dye (trade name “NKX 1658” supplied by Hayashibara Biochemical Laboratories, Inc.) as a sensitizing dye (D′) in 30 parts by weight of cyclohexanone. A hologram recording medium Y-7 was prepared by the procedure of Example Y-1, except for dropping the photosensitive composition Y-5 onto a glass substrate, spreading thereon using an applicator so as to have a dry thickness of 50 μm, and drying at room temperature under light-shielding conditions for 20 hours. Using this medium, a hologram recording was performed by the procedure of Example Y-1. As a result, the diffraction efficiency was 32%, and the shrinkage percentage was 0.8%.

### Example Y-8

As a photo-induced cationically polymerizable compound (B′), a 2:1 (by mole) mixture of a bifunctional alicyclic epoxy compound (3,4,3′,4′-diepoxybicyclohexyl) and a bifunctional vinyl ether-monofunctional oxetane compound (3,3-dimethanol divinyl ether oxetane) was subjected to a heating treatment on an oil bath at 100° C. in an air atmosphere for 30 minutes. Next, a photosensitive composition Y-6 was prepared by dissolving 100 parts by weight of the heat-treated cationically polymerizable compound (B′), 60 parts by weight of a poly-2-vinylnaphthalene (Mw=93,000) as a binder polymer (A′), 10 parts by weight of a diphenyliodonium compound (trade name “PI 2074” supplied by Rhodia) as a photoinitiator (C′), and 0.5 part by weight of a coumarin dye (trade name “NKX 1658” supplied by Hayashibara Biochemical Laboratories, Inc.) as a sensitizing dye (D′) in 30 parts by weight of cyclohexanone. A hologram recording medium Y-8 was prepared by the procedure of Example Y-1, except for dropping the photosensitive composition Y-6 onto a glass substrate, spreading thereon using an applicator so as to have a dry thickness of 50 μm, and drying at room temperature under light-shielding conditions for 20 hours. Using this medium, a hologram recording was performed by the procedure of Example Y-1. As a result, the diffraction efficiency was 40%, and the shrinkage percentage was 0.8%.

### Example Y-9

As a photo-induced cationically polymerizable compound (B′), a 7:1 (by mole) mixture of a bifunctional alicyclic epoxy compound (3,4-epoxycyclohexylmethyl-3′,4′-epoxycyclohexanecarboxylate, supplied under the trade name “CEL 2021P” by Daicel Chemical Industries, Ltd.) and a bifunctional vinyl ether compound (oxynorbornene divinyl ether) was subjected to a heating treatment on an oil bath at 100° C. in an air atmosphere for 30 minutes. Next, a photosensitive composition Y-7 was prepared by dissolving 100 parts by weight of the heat-treated cationically polymerizable compound (B′), 60 parts by weight of a poly-2-vinylnaphthalene (Mw=93,000) as a binder polymer (A′), 10 parts by weight of a diphenyliodonium compound (trade name “PI 2074” supplied by Rhodia) as a photoinitiator (C′), and 0.5 part by weight of a coumarin dye (trade name “NKX 1658” supplied by Hayashibara Biochemical Laboratories, Inc.) as a sensitizing dye (D′) in 30 parts by weight of cyclohexanone. A hologram recording medium Y-9 was prepared by the procedure of Example Y-1, except for dropping the photosensitive composition Y-7 onto a glass substrate, spreading thereon using an applicator so as to have a dry thickness of 50 μm, and drying at room temperature under light-shielding conditions for 20 hours. Using this medium, a hologram recording was performed by the procedure of Example Y-1. As a result, the diffraction efficiency was 10%, and the shrinkage percentage was 2.4%.

### Comparative Example Y-1

A photosensitive composition Y-8 was prepared by the procedure of Example Y-1, except for not performing the heating treatment of the photo-induced cationically polymerizable compound (B′). Using this composition, a hologram recording medium was prepared, and a hologram recording was performed by the procedure of Example Y-2. As a result, the diffraction efficiency was 25%, and the shrinkage percentage was 0.5%.

### Comparative Example Y-2

A photosensitive composition Y-9 was prepared by the procedure of Example Y-4, except for not performing the heating treatment of the photo-induced cationically polymerizable compound (B′). Using this composition, a hologram recording medium was prepared, and a hologram recording was performed by the procedure of Example Y-4. As a result, the diffraction efficiency was 23%, and the shrinkage percentage was 0.4%.

### Comparative Example Y-3

A photosensitive composition Y-10 was prepared by the procedure of Example Y-5, except for not performing the heating treatment of the photo-induced cationically polymerizable compound (B′). Using this composition, a hologram recording medium was prepared, and a hologram recording was performed by the procedure of Example Y-5. As a result, the diffraction efficiency was 23%, and the shrinkage percentage was 0.4%.

### Comparative Example Y-4

A photosensitive composition Y-11 was prepared by the procedure of Example Y-6, except for not performing the heating treatment of the photo-induced cationically polymerizable compound (B′). Using this composition, a hologram recording medium was prepared, and a hologram recording was performed by the procedure of Example Y-6. As a result, the diffraction efficiency was 15%, and the shrinkage percentage was 0.8%.

### Comparative Example Y-5

A photosensitive composition Y-12 was prepared by the procedure of Example Y-7, except for not performing the heating treatment of the photo-induced cationically polymerizable compound (B′). Using this composition, a hologram recording medium was prepared, and a hologram recording was performed by the procedure of Example Y-7. As a result, the diffraction efficiency was 19%, and the shrinkage percentage was 0.9%.

### Comparative Example Y-6

A photosensitive composition Y-13 was prepared by the procedure of Example Y-8, except for not performing the heating treatment of the photo-induced cationically polymerizable compound (B′). Using this composition, a hologram recording medium was prepared, and a hologram recording was performed by the procedure of Example Y-8. As a result, the diffraction efficiency was 20%, and the shrinkage percentage was 1%.

### INDUSTRIAL APPLICABILITY

The photosensitive composition (I) for volume hologram recording according to the present invention exhibits superior refractive-index modulability, has high polymerization reactivity, and shows very small volume shrinkage. The method for producing a photosensitive composition (II) for volume hologram recording according to the present invention allows simple and efficient production of the photosensitive composition (II) for volume hologram recording which exhibits superior refractive-index modulability, shows very small volume shrinkage, and achieves high diffraction efficiency. The photosensitive compositions (I) and (II) for volume hologram recording thereby give holograms which excel typically in diffraction efficiency and reproducibility. The methods for producing a volume hologram recording medium according to the present invention allow simple and efficient production of volume hologram recording media which excel in holographic properties such as diffraction efficiency.

1. A photosensitive composition (I) for volume hologram recording, comprising a binder polymer (A); a photo-induced cationically polymerizable compound (B); a photoinitiator (C); and a sensitizing dye (D), wherein the binder polymer (A) is a polymer containing naphthalene rings and having a weight-average molecular weight of 1×10⁴ to 100×10⁴.

2. The photosensitive composition (I) for volume hologram recording according to claim 1, wherein the photo-induced cationically polymerizable compound (B) is a compound intramolecularly having one or more of at least one cationically polymerizable group selected from the group consisting of epoxy group, vinyl ether group, and oxetanyl group.

3. The photosensitive composition (I) for volume hologram recording according to claim 1 or 2, wherein the binder polymer (A) has a refractive index higher than the refractive index of the photo-induced cationically polymerizable compound (B) with a difference between the two refractive indices of from 0.001 to 0.4.

4. The photosensitive composition (I) for volume hologram recording according to claim 1, wherein the photosensitive composition shows a percentage of volume shrinkage of 1% or less after a hologram recording with reference to the volume before the hologram recording.

5. A method for producing a volume hologram recording medium, the method comprising the step of applying the photosensitive composition (I) for volume hologram recording according to claim 1 to a base or substrate to form a volume holographic material layer thereon.

6. The method for producing a volume hologram recording medium, according to claim 5, further comprising the step of covering the volume holographic material layer after or during the formation thereof with a second base or substrate, the second base or substrate including the same material as that of the base or substrate to which the photosensitive composition (I) for volume hologram recording has been applied.

7. The method for producing a volume hologram recording medium, according to claim 5 or 6, comprising the steps of applying the photosensitive composition (I) for volume hologram recording to a first base or substrate so as to give a volume holographic material layer having a thickness of 10 to 2000 μm; covering the coated layer with a second base or substrate to give a laminate, the second base or substrate including the same material as that of the first base or substrate; sealing the periphery of the laminate; and aging the sealed laminate for a given time.

8. A cured article derived from the photosensitive composition (I) for volume hologram recording according to claim 1 through photo-induced cationic curing.

9. A method for producing a photosensitive composition (II) for volume hologram recording, the method comprising the step of mixing a binder polymer (A′), a photo-induced cationically polymerizable compound (B′), a photoinitiator (C′), and a sensitizing dye (D′) to give the photosensitive composition for volume hologram recording, wherein the photo-induced cationically polymerizable compound (B′) has been previously subjected to a heating treatment at a temperature equal to or lower than the boiling point of the compound (B′).

10. The method for producing a photosensitive composition (II) for volume hologram recording, according to claim 9, wherein the photo-induced cationically polymerizable compound (B′) is a compound intramolecularly having one or more of at least one cationically polymerizable group selected from the group consisting of epoxy group, vinyl ether group, and oxetanyl group.

11. The method for producing a photosensitive composition (II) for volume hologram recording, according to claim 9 or 10, wherein the binder polymer (A′) has a refractive index higher than the refractive index of the photo-induced cationically polymerizable compound (B′) with a difference between the two refractive indices of from 0.001 to 0.5.

12. A photosensitive composition (II) for volume hologram recording, as a product produced by the production method according to claim 9.

13. The photosensitive composition (II) for volume hologram recording, according to claim 12, wherein the photosensitive composition shows a percentage of volume shrinkage of 1% or less after a hologram recording with reference to the volume before the hologram recording.

14. A method for producing a volume hologram recording medium, the method comprising the step of applying the photosensitive composition (II) for volume hologram recording according to claim 12 or 13 to a base or substrate to form a volume holographic material layer thereon.

15. The method for producing a volume hologram recording medium, according to claim 14, further comprising the step of covering the volume holographic material layer after or during the formation thereof with a second base or substrate, the second base or substrate including the same material as that of the base or substrate to which the photosensitive composition (II) for volume hologram recording has been applied.

16. The method for producing a volume hologram recording medium, according to claim 14, comprising the steps of applying the photosensitive composition (II) for volume hologram recording to a first base or substrate so as to give a volume holographic material layer having a thickness of 10 to 2000 μm; covering the coated layer with a second base or substrate to give a laminate, the second base or substrate including the same material as that of the first baser or substrate; sealing the periphery of the laminate; and aging the sealed laminate for a given time.

17. A cured article derived from the photosensitive composition (II) for volume hologram recording according to claim 12 or 13 through photo-induced cationic curing.
